(19) United States
(12) Patent Application Publication
(10) Pub. No.: US 2003/0052571 A1
(43) Pub. Date: Mar. 20, 2003

(54) Method for attaching resonator part

(75) Inventor: Esa Mikkonen, Oulu (FI)

Correspondence Address: DARBY & DARBY P.C., Post Office Box 5257, New York, NY, 10150-5257, US

(73) Assignee: Filtronic LK Oy

(21) Appl. No.: 10/285,762

(22) Filed: Nov. 1, 2002

Related U.S. Application Data
(62) Division of application No. 09/902,852, filed on Jul. 10, 2001.

(30) Foreign Application Priority Data
Jul. 17, 2000 (FI) 20001676

(51) Int. Cl. H02N 2/00; H01L 41/04; H01L 41/08; H01L 41/18

(52) U.S. Cl. 310/311

(57) ABSTRACT

A method for attaching a part to a body of a resonator, which body is made by the process of extruding. In a pushing part (ES) of an extrusion machine is made a recess, which is shaped like a portion of the surface of the additional object. An additional object (320), such as a portion of the inner conductor of a resonator, is inserted prior to extrusion in said recess so that said portion of the surface of the additional object rests tightly against the surface of the recess and the rest of the surface of the additional object remains free. In the extrusion stage, the pushing part with the additional object is pressed (F) against a bloom of a resonator body whereby the material (31c) of the bloom is pressed tight against the free surface of the additional object. When the pushing part is retracted the additional object remains attached to the body element. Thus parts may be added to the body element in conjunction with the manufacturing of the body element without separate manufacturing steps, and the resulting joint is strong and uniform. The extrusion machine may have several pushing parts, in each of which is inserted an additional object, to manufacture a filter, which comprises several inner conductors.

The invention relates to a method for attaching a part to a body of a resonator, which body is made by the process of extruding. The resonator may be a portion of a resonator filter.

Air-insulated coaxial resonators are popular e.g. in radio-frequency filters at base stations of mobile communication networks because of their relatively good electrical characteristics and good manufacturability. A coaxial resonator is most often a quarter-wave resonator where one end of the resonator is short-circuited, ie. the inner conductor and outer conductor of the resonator are in galvanic contact, and the other end is open. When manufacturing a filter comprising a plurality of resonators, it has to be taken into account that the desired frequency response of the filter may require inner conductors of different lengths. In addition, it may be necessary to compensate for the change in the resonance frequency caused by thermal expansion in the resonator structure.

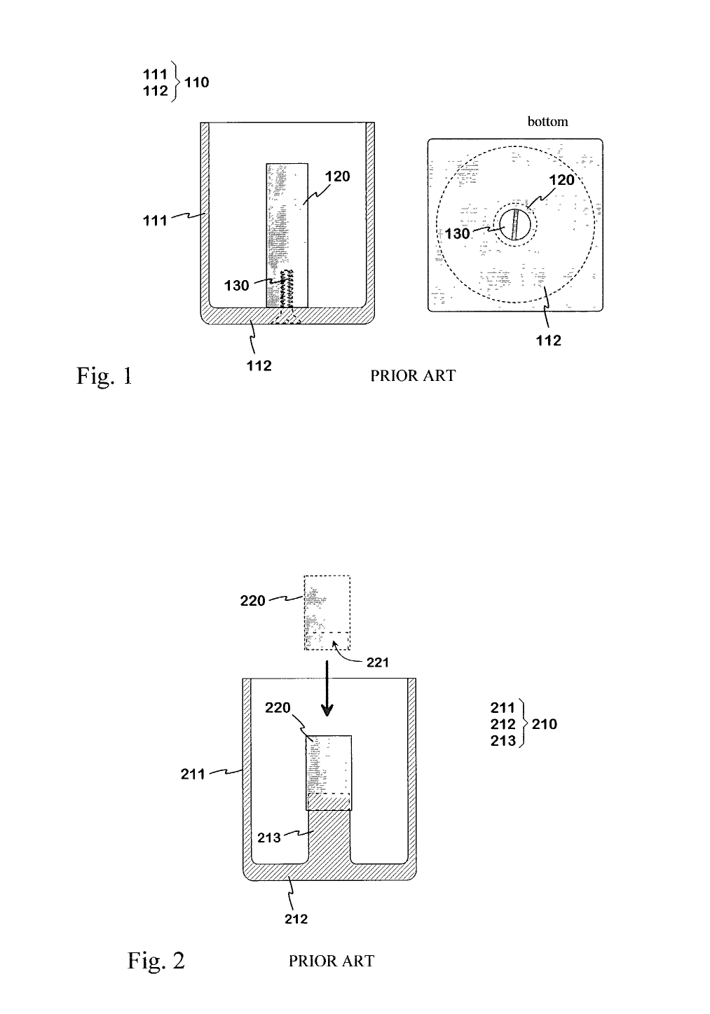

There are several known methods for manufacturing coaxial resonators functioning as filter elements. FIG. 1 depicts a known structure viewed from the side and from the bottom. Shown in the figure is the resonator's outer conductor 111, inner conductor 120, and the bottom 112. The outer conductor and the bottom are shown in longitudinal section. They constitute a single body 110 having a quadrangular cross section and a cylinder-shaped cavity. The body 110 is manufactured by the process of milling or extruding, for example. The inner conductor is in the said cavity, attached to the bottom 112 of the resonator so that the bottom provides the short circuit between the inner and outer conductor. In this example, the attachment of the inner conductor is realized using a screw 130 extending through the bottom to the inner conductor. The inner conductor may be of the same or different material than the body 110. In the latter case, the temperature compensation in the resonator may be realized through the choice of materials.

A disadvantage of the method appearing in FIG. 1 is that the attachment of the inner conductor takes several manufacturing stages and the attachment strength does not meet the strictest requirements. Moreover, the interfaces between the different metals in the structure may cause harmful intermodulation products when using the device.

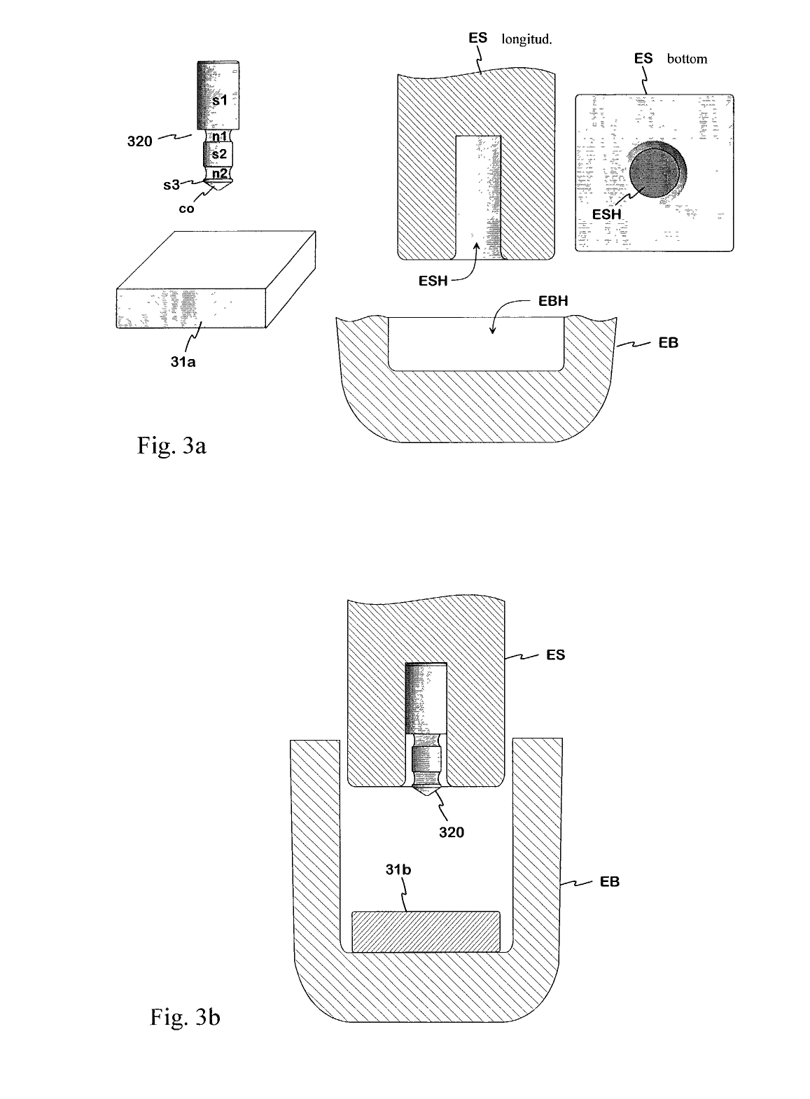

FIG. 2 shows a longitudinal section of another known structure. The figure shows the resonator's outer conductor 211 and bottom 212. The resonator's inner conductor has now two parts: A lower part 213 nearer the bottom of the resonator and an upper part 220 forming a continuation of the lower part. In this example, the lower part 213 of the inner conductor, bottom 212 and the outer conductor 211 constitute a single body 210. At the bottom end of the upper part of the inner conductor there is a cylindrical hollow 221 the diameter of which equals that of the lower part of the inner conductor. Thus the upper part 220 may be pushed onto the lower part 213 as a cap. The purpose of the upper part of the inner conductor is to provide for the temperature compensation in the resonator. A disadvantage of the manufacturing method appearing in FIG. 2 is that the attachment of the inner conductor requires a separate manufacturing stage. Moreover, in this case, too, the risk of harmful intermodulation is apparent at the boundary surface of pressing joint.

An object of the invention is to reduce the above-mentioned disadvantages associated with the prior art. The method according to the invention is characterized by that which is specified in the independent claim 1. Some preferred embodiments of the invention are specified in the other claims.

The basic idea of the invention is as follows: A resonator body is manufactured by means of extrusion. In the pushing part of the extrusion machine a recess is made which is shaped like a portion of the surface of the additional object to be attached to the body. The additional object, such as a portion of an inner conductor, is inserted prior to the extrusion in the recess so that said portion of the surface of the additional object is positioned tightly against the surface of the recess and the rest of the surface of the additional object remains free. In the extrusion stage, the pushing part with the additional object is pressed against the bloom of body whereby the material of the bloom is pressed tight against the free surface of the additional object. When the pushing part is retracted the additional object remains attached to the body thus formed. The extrusion machine may have several pushing parts, whereupon several additional objects will be attached at the same time in a manufacturing process of a filter.

An advantage of the invention is that in conjunction with the manufacturing of the body part of the structure being manufactured, parts may be added to the body without separate manufacturing steps. This means savings in the manufacturing costs. Another advantage of the invention is that the joint according to the invention between the additional part and body part is stronger and more uniform than similar prior-art joints. This means higher reliability of the structure and less intermodulation at the boundary surface of the joint. A further advantage of the invention is that in the case of several additional objects the inner conductors of the different resonators may be manufactured in different lengths, if necessary, by using recesses of different lengths in the pushing parts of the extrusion machine. The additional objects to be attached to the inner conductors may then be identical, which is advantageous from the standpoint of manufacture.

The invention is described in more detail in the following. Reference is made to the accompanying drawings in which

FIG. 1 shows an example of a method for attaching a part to a resonator, according to the prior art,

FIG. 2 shows another example of a method for attaching a part to a resonator, according to the prior art,

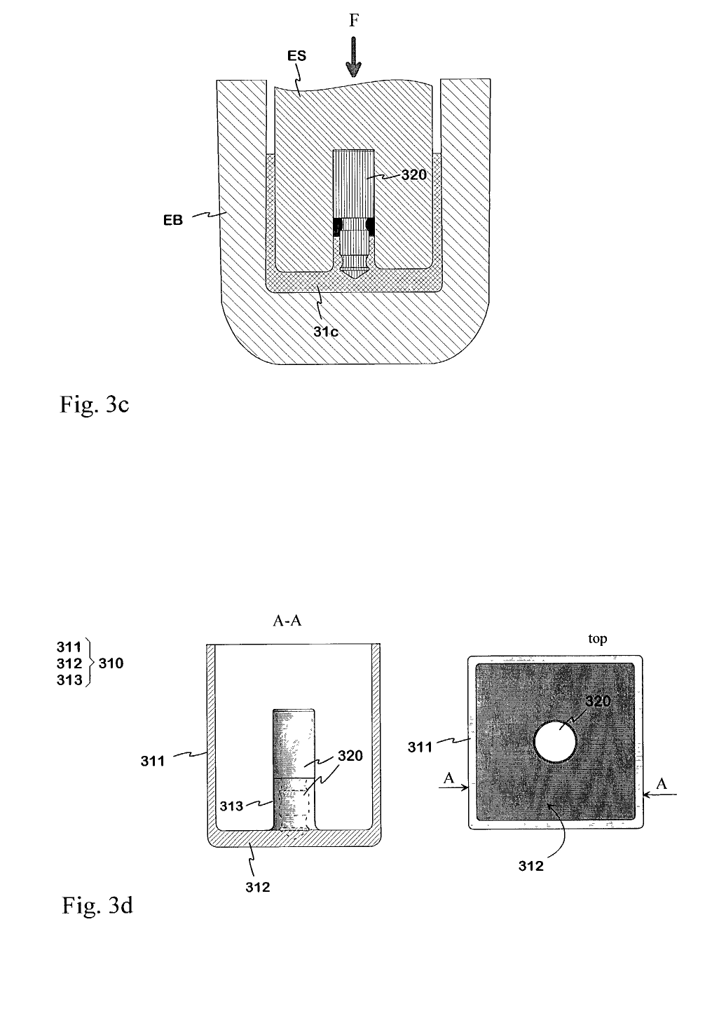

FIGS. 3a-d show an example of a method according to the invention and resulting resonator,

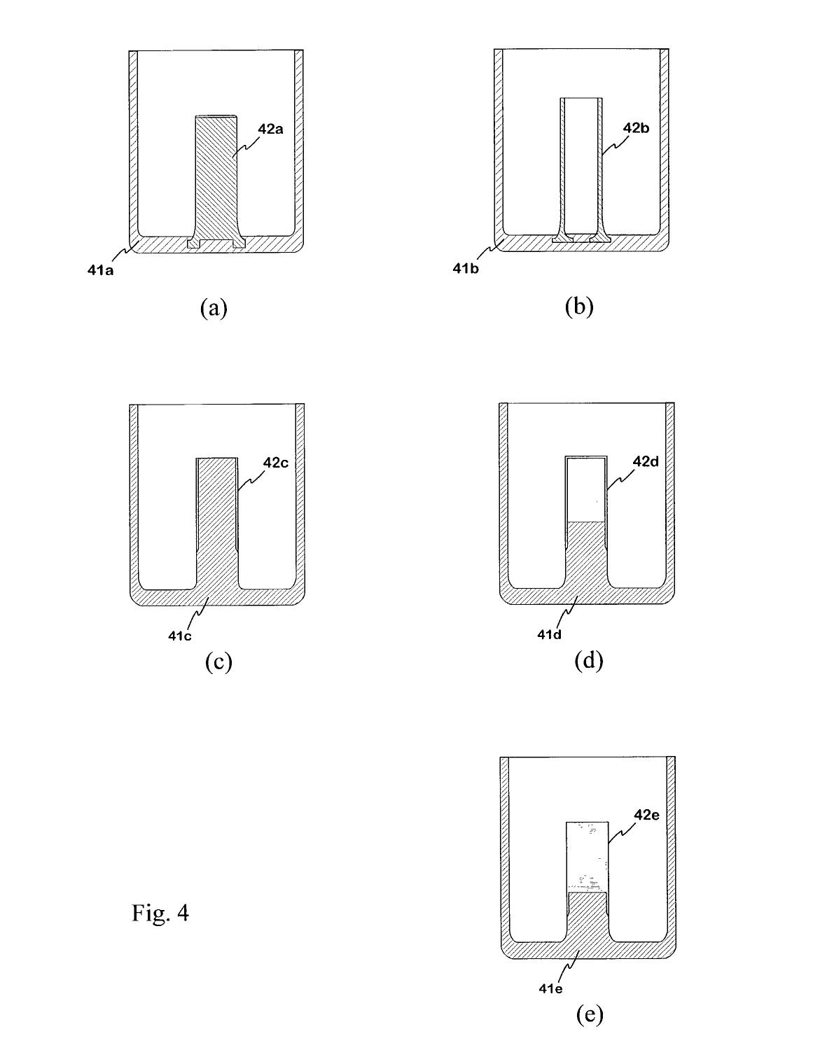

FIG. 4 shows more examples of a resonator manufactured according to the invention, and

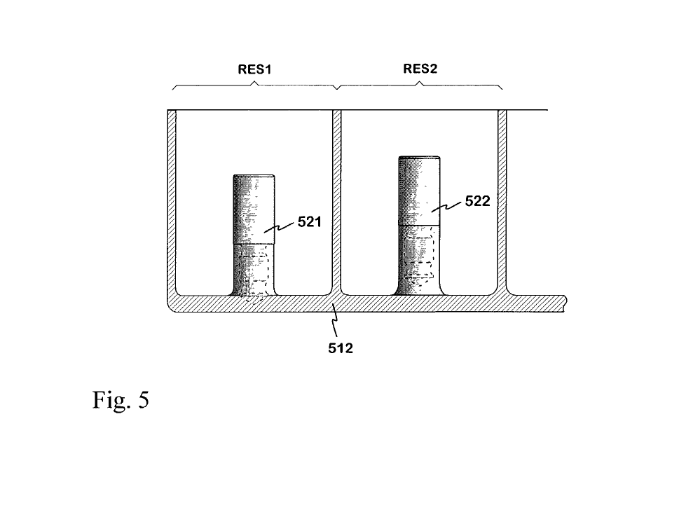

FIG. 5 shows an example of a filter manufactured by the method according to the invention.

FIGS. 1 and 2 were already discussed in conjunction with the description of the prior art.

FIG. 3a depicts an initial situation of the manufacturing method according to the invention. Shown in the figure is a bloom 31a of a resonator body, an additional object 320 to be attached to the body structure, an extrusion base EB serving as a mold, and a pushing part ES of an extrusion machine. The additional object 320 is drawn vertical. In this example it comprises on one and the same axis a cylindrical upper part s1 and a lower part having a first neck section n1, a second cylinder section s1, a second neck section n2, a third cylinder section s3 and a cone section co. The second and third cylinder sections are rounded at the corners. The diameter of the upper part is greater than the diameter of the lower part at any point. The shape of the bloom 31a is a rectangular prism. The extrusion base EB is drawn in FIG. 3a in longitudinal section and the upper part cut out. It has in the center a recess EBH that corresponds to the outer dimensions of the object to be manufactured. The pushing part ES of the extrusion machine is depicted both in longitudinal section and viewed from below. The dimensions of the cross section of the pushing part correspond to the inner dimensions of the cross section of the body of the object to be manufactured. The pushing part has a recess ESH according to the invention. The cylindrical recess ESH starts from the lower surface of the pushing part and its diameter is substantially the same as the diameter of the upper part of the additional object.

In FIG. 3b the bloom 31b is placed on the extrusion base EB. An additional object 320 is placed in the recess of the pushing part ES of the extrusion machine. The diameters of the upper part of the additional object and the recess of the pushing part correspond to each other so that the additional object, when its upper part is suitably lubricated, fits tightly into the recess. In this example the length of the recess of the pushing part is such that the conic lowest section of the additional object 320 remains below the lower surface of the pushing part. An empty space is left around the lower part of the additional object.

FIG. 3c depicts the extrusion stage. The pushing part ES is pressed at a force F downward against the bloom. The pressure forces the material 31c of the bloom to spread into free spaces, which include the relatively narrow space between the walls of the extrusion base EB and pushing part ES and the space around the lower part of the additional object in the recess of the pushing part. In the situation of FIG. 3c the latter space has been a bit over half filled. As the downward movement of the pushing part ES ceases, the body material 31c has totally filled the space around the lower part of the additional object and risen between the walls into the designated height. After that, the pushing part ES is pulled back up. The additional object 320 remains attached to the body part thus formed. The joint between the body part and the additional object achieved in the manner described is strong because the metallic extrusion material tightly fills up the space around the lower part of the additional object. The shape of the lower part of the additional object according to this example adds to the strength of the bond: Said two neck sections n1 and n2 having cylinder surfaces constricted at the middle provide excellent attachment points.

FIG. 3d shows a longitudinal section and a top view of a resonator structure removed from the extrusion base. The cross section of the outer conductor 311 of the resonator structure is quadrangular in accordance with the shape of the extrusion base and pushing part of the extrusion machine. A homogeneous body part 310 comprises the outer conductor 311, bottom 312 and conductive material 313 around the lower part of the additional object 320. The inner conductor of the resonator comprises said conductive material 313 and additional object 320 excluding the cone section. The cone section remains within the bottom 312. FIG. 3d shows a single resonator (without a cover) produced by the manufacturing stage at issue.

FIG. 4 shows in longitudinal sections further examples of resonators manufactured according to the invention. In the sub-FIG. (a) the additional object 42a is a cylindrical object the lower part of which spreads into a flange-like base. In the extrusion stage the additional object fills the recess in the pushing part of the extrusion machine in its entirety. The base part of the additional object remains outside the recess so that it lies inside the bottom of the resonator body 41a after the extrusion has been completed. The inner conductor of the resonator comprises the additional object 42a excluding the part that remains inside the resonator bottom.

In sub-FIG. 4(b) the additional object is an object shaped like a cylinder mantle, in the lower part of which the cylinder walls spread into a flange-like base. In the extrusion stage the additional object 42b fills the recess in the pushing part of the extrusion machine in its entirety but the recess itself is now shaped like a cylinder mantle. The base part of the additional object remains outside the recess so that it lies inside the bottom of the resonator body 41b after the extrusion has been completed. The inner conductor of the resonator comprises the additional object 42b excluding the part that remains inside the resonator bottom.

In sub-FIG. 4(c) the additional object 42c is a thin-walled object shaped like a cylinder mantle. In the extrusion stage the additional object is in the pushing part's recess shaped like an open cylinder so that the additional object does not reach the edge of the recess. Extrusion thus produces in the body part 41c a cylindrical inner conductor around the upper end of which the additional object is attached.

In sub-FIG. 4(d) the additional object 42d is a relatively thin-walled object comprising a cylinder mantle and one end. In the extrusion stage the additional object is positioned in the pushing part's recess, which is shaped like an open cylinder, so that its closed end is in the bottom of the recess and the open end does not reach the edge of the recess. The recess in the pushing part, additional object and the bloom of the resonator body are dimensioned such that in the extrusion, the material of the bloom extends inside the additional object but fills it only partly. Thus is produced a resonator inner conductor comprising a cylindrical part in the body 41d and additional object 42d around its upper end. In accordance with the above, the body extends only partly inside the additional object, so the upper end of the inner conductor is hollow.

In sub-FIG. 4(e) the additional object 42e is a cylindrical object having at one end a cylindrical recess the diameter of which is nearly the same as that of the additional object. In the extrusion stage the additional object is positioned in the recess of the pushing part of the extrusion machine, which recess is shaped like an open cylinder, so that its solid end is in the bottom of the recess of the pushing part and the open end does not reach the edge of the recess. In the extrusion, the material of the bloom fills entirely the recess of the open end of the additional object. Thus is produced a resonator inner conductor the lower part of which comprises a cylindrical part in the body 41e and the upper part of which comprises the additional object 42e. In accordance with the above, the additional object is compressed around the upper end of the lower part of the inner conductor.

Using the method described it is possible to manufacture at one time a whole filter body with several attached objects by means of an extrusion machine with several pushing parts. The recesses in the pushing parts may have different depths. Using a recess in which the additional object can be inserted in its totality, the additional object in the finished product will be positioned higher from the bottom of the structure than in FIG. 3d. Thus in the filter the resonators may have inner conductors of different lengths, if necessary, even when the additional objects are identical. FIG. 5 shows an example of such a structure. In the figure is seen a filter body 512, a first resonator RES1 having additional object 521 and a second resonator RES2 having additional object 522. The inner conductor of the resonator RES1 is shorter than the inner conductor of another resonator RES2.

In all versions of the resonator or filter manufactured according to the invention, the additional objects attached to the body are primarily used for temperature compensation in the resonator. The body part is advantageously aluminum and the additional objects may be copper or steel, for example.

Above it was described the method according to the invention and some structures according to it. The invention is not limited solely to those. The shapes of the objects belonging to the structure may understandably vary a great deal. The inventional idea may be applied in various ways within the scope defined by the independent claim.

1. A method for attaching an additional object to a body element of a resonator, which additional object has a first and a second surface, and which body element is manufactured by the process of extrusion, wherein said attaching takes place in conjunction with said extrusion, the method comprising steps;
the additional object is placed in a recess made in pushing part of an extrusion machine so that the first surface rests against the surface of the recess and the second surface is surrounded by air,
the pushing part is pressed against a bloom of the body element to form the body element and to press material of the body element against the second surface, and
the pushing part is pulled back from the resulting body element and from the additional object attached thereto.

2. The method according to claim 1, the additional object comprising in sequence a first cylinder part, a first neck part and a second cylinder part, all said parts having the same axis and the neck part having a smaller diameter than the second cylinder part, wherein the first surface consists of the cylindrical surface and surface of one end of the first cylinder part and the second surface is the remaining surface of the additional object.

3. The method according to claim 1, the additional object being a cylindrical object one end of which is flange-like and larger in diameter than the rest of the additional object, wherein the first surface substantially consists of the surface of that part of the additional object which has the same diameter throughout and the second surface substantially consists of the surface of said flange-like portion.

4. The method according to claim 1, the additional object being an object shaped like a cylindrical mantle one end of which is a flange-like ring and larger in diameter than the rest of the additional object, wherein the first surface substantially consists of the outer and inner surfaces of that part of the additional object which has the same diameter throughout and the second surface substantially consists of the surface of said flange-like portion.

5. The method according to claim 1, the additional object being an object shaped like a cylindrical mantle, wherein the first surface consists of the outer surface of the additional object and the second surface consists of the inner surface of the additional object.

6. The method according to claim 1, the additional object being a hollow cylindrical object one end of which is open, wherein the first surface consists of the outer surface of the additional object and the second surface consists of a part of the inner surface of the additional object.

7. The method according to claim 1, the additional object being a cylindrical object one end of which is solid and the other end has a recess in it, wherein the first surface consists of the outer cylindrical surface of the additional object and the surface of the solid end, and the second surface consists of the surface of the open end and the surface of the recess in the open end of the additional object.

8. The method according to claim 1, said extrusion machine further having at least a second pushing part, a second additional object being placed in a recess of the second pushing part and pushing parts being pressed at the same time against a bloom of the body element to manufacture a resonator filter, which comprises at least two inner conductors.

9. The method according to claim 8, said additional objects being substantially identical and recesses in said pushing parts having different depths to form inner conductors of different lengths.
